(19) United States
(12) Patent Application Publication
(10) Pub. No.: US 2023/0403874 A1
(43) Pub. Date: Dec. 14, 2023

(54) LIGHT-EMITTING ELEMENT, DISPLAY DEVICE AND LIGHT-EMITTING ELEMENT MANUFACTURING METHOD

(71) Applicant: SHARP KABUSHIKI KAISHA, Sakai City, Osaka (JP)

(72) Inventor: Ryo KITAMURA, Sakai City, Osaka (JP)

(21) Appl. No.: 18/033,847

(22) PCT Filed: Oct. 30, 2020
(86) PCT No.: PCT/JP2020/040833

§ 371 Date: Apr. 26, 2023

(51) Int. Cl. H10K 50/115; C09K 11/88; C09K 11/08

(52) U.S. Cl. CPC H10K 50/115; C09K 11/883; C09K 11/0883; B82Y 20/00

(57) ABSTRACT

A light-emitting element includes a first light-emitting layer including a plurality of first quantum dots and a plurality of spacer particles. The plurality of first quantum dots each includes a first core and a first shell coating the first core and having an outermost layer containing either a metal chalcogenide complex or a metal chalcogenide compound.

### TECHNICAL FIELD

The present disclosure relates to a light-emitting element, a display device including the light-emitting element, and a light-emitting element manufacturing method.

### BACKGROUND ART

In recent years, quantum-dot light-emitting diodes (QLEDs) as light-emitting elements, and display devices including the QLEDs, have attracted widespread attention.

However, a typical QLED currently under development includes a light-emitting layer containing: quantum dots (QDs) emitting light; and organic ligands bonding to the quantum dots. A problem of the QLED is that the organic ligands themselves are prone to deterioration and desorption from the quantum dots. As a result, the QLED is not sufficiently reliable.

Hence, for example, Patent Document 1 describes a layer containing quantum dots each including: a core; and a shell whose outermost layer contains a metal chalcogenide compound, and the quantum dots are embedded in a matrix containing metal chalcogenide. The layer is used as a light-emitting layer.

### CITATION LIST

### Patent Document

[Patent Document 1] United States Patent Application Publication No. 2013/0146834A1

### SUMMARY OF INVENTION

### Technical Problem

However, as described in Patent Document 1, if the layer, whose quantum dots are embedded in a matrix containing metal chalcogenide, is used as a light-emitting layer of a light-emitting element that emits light by electroluminescence (EL), the matrix containing the metal chalcogenide with low bandgap and low electrical resistance inevitably causes a leak of a current. The current leak interferes injection of carriers into the cores of the quantum dots, developing a problem of hindering improvement in light emission efficiency.

An aspect of the present disclosure is conceived in view of the above problem, and intended to provide a light-emitting element that reduces a leak of a current in the light-emitting layer and that improves reliability and light emission efficiency. The present disclosure is also intended to provide a display device including the light-emitting element and a light-emitting element manufacturing method.

### Solution to Problem

In order to solve the above problem, a light-emitting element according to the present disclosure includes:
a first electrode;
a second electrode disposed across from the first electrode;
a first light-emitting layer disposed between the first electrode and the second electrode, and
including a plurality of first quantum dots and a spacer particle, the plurality of first quantum dots each including a first core and a first shell coating the first core and having an outermost layer containing either a metal chalcogenide complex or a metal chalcogenide compound.

In order to solve the above problem, a display device according to the present disclosure includes:
a plurality of the light-emitting elements,
wherein the plurality of light-emitting elements include a first light-emitting element and a second light-emitting element,
the first light-emitting element includes, in the first light-emitting layer, a long-wavelength light-emitting core as the first core and a first spacer particle as the spacer particle,
the second light-emitting element includes, in the first light-emitting layer, a short-wavelength light-emitting core as the first core and a second spacer particle as the spacer particle,
the long-wavelength light-emitting core has a peak emission wavelength longer than a peak emission wavelength of the short-wavelength light-emitting core, and
the first spacer particle is smaller in particle size than the second spacer particle.

In order to solve the above problem, a display device according to the present disclosure includes:
a first light-emitting element and a second light-emitting element,
wherein the first is included in the plurality of light-emitting elements,
the first light-emitting element includes, in the first light-emitting layer, the first core and the spacer particle,
the second light-emitting element includes:
a third electrode;
a fourth electrode disposed across from the third electrode; and
a second light-emitting layer disposed between the third electrode and the fourth electrode, and including a plurality of second quantum dots each including a third core having a peak emission wavelength shorter than a peak emission wavelength of the first core, and
the second light-emitting layer contains a less amount of a plurality of the spacer particles than the first light-emitting layer does.

In order to solve the above problem, a light-emitting element manufacturing method according to the present disclosure includes:
a step of forming a multilayer stack including a first electrode;
a step of coating the multilayer stack with a solution including a plurality of quantum dots and a spacer particle, the plurality of first quantum dots each including a first core and a first shell coating the first core and having an outermost layer containing either a metal chalcogenide complex or a metal chalcogenide compound; and
a step of at least irradiating the solution with an ultraviolet light or heating the solution, and of forming a light-emitting layer including clearance to provide a distance between at least two quantum dots included in the plurality of first quantum dots and positioned next to each other.

### Advantageous Effects of Invention

An aspect of the present disclosure can provide a light-emitting element that reduces a leak of a current in the light-emitting layer and that improves reliability and light emission efficiency. The present disclosure is also intended to provide a display device including the light-emitting element and a light-emitting element manufacturing method.

### BRIEF DESCRIPTION OF DRAWINGS

FIG. 1 is a cross-sectional view of a schematic configuration of a light-emitting element according to a first embodiment.

FIG. 2 is a view of a schematic configuration of a light-emitting layer included in the light-emitting element according to the first embodiment.

FIG. 3(a) is a view of a schematic configuration of a quantum dot, before and after irradiated with a UV light or treated with heat, contained in the light-emitting layer included in the light-emitting element of the first embodiment. FIG. 3(b) is a TEM image of quantum dots before irradiated with a UV light or treated with heat. FIG. 3(c) is a TEM image of quantum dots after irradiated with a UV light or treated with heat.

FIG. 4(a) is a view of a schematic configuration of a light-emitting layer included in a modification of the light-emitting element according to the first embodiment. FIG. 4(b) is a schematic band diagram of the light-emitting layer included in the modification of the light-emitting element according to the first embodiment.

FIG. 5 is a graph showing preferable materials of spacer particles.

FIG. 6(a), FIG. 6(b), and FIG. 6(c) are diagrams showing preferable materials of spacer particles

FIG. 7 is a view showing a preferable volume ratio of the spacer particles to the light-emitting element included in the light-emitting element according to the first embodiment.

FIG. 8 is a view of a schematic configuration of a light-emitting layer included in another modification of the light-emitting element according to the first embodiment.

FIG. 9 is a plan view of a schematic configuration of a display device according to a second embodiment.

FIG. 10(a) is a view of an example of a red light-emitting element included in the display device according to the second embodiment illustrated in FIG. 9. FIG. 10(b) is a view of an example of a green light-emitting element included in the display device according to the second embodiment illustrated in FIG. 9. FIG. 10(c) is a view of an example of a blue light-emitting element included in the display device according to the second embodiment illustrated in FIG. 9.

FIG. 11(a) is a view of a schematic configuration of a light-emitting layer included in the green light-emitting element illustrated in FIG. 10(b). FIG. 11(b) is a view of a schematic configuration of a light-emitting layer included in the blue light-emitting element illustrated in FIG. 10(c).

FIG. 12(a) is a band diagram of a plurality of kinds of Cd cores having different peak emission wavelengths. FIG. 12(b) is a band diagram of a plurality of kinds of InP cores having different peak emission wavelengths. FIG. 12(c) is a band diagram of a plurality of kinds of ZnSe cores having different peak emission wavelengths.

FIG. 13(a) is a view of an example of a red light-emitting element included in a display device according to a third embodiment. FIG. 13(b) is a view of an example of a green light-emitting element included in the display device according to the third embodiment. FIG. 13(c) is a view of an example of a blue light-emitting element included in the display device according to the third embodiment.

FIG. 14(a) is a view of a schematic configuration of a light-emitting layer included in the green light-emitting element illustrated in FIG. 13(b). FIG. 14(b) is a view of a schematic configuration of a light-emitting layer included in the blue light-emitting element illustrated in FIG. 13(c).

### DESCRIPTION OF EMBODIMENTS

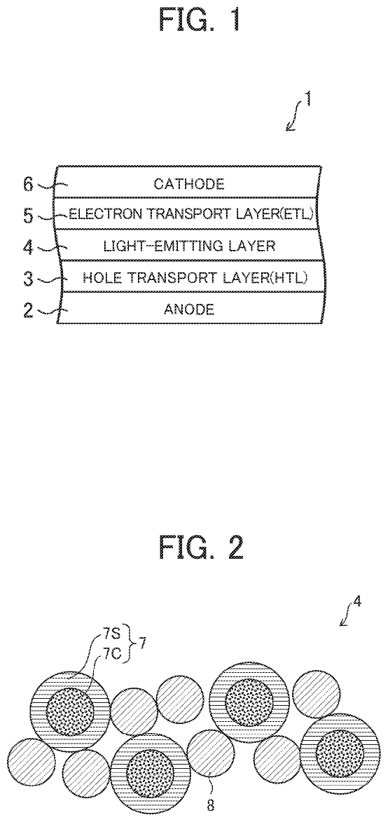

Described below are embodiments of the present invention, with reference to FIGS. 1 to 14. For convenience in description, like reference signs designate identical constituent features throughout specific embodiments. These constituent features will not be elaborated upon.

### First Embodiment

FIG. 1 is a cross-sectional view of a schematic configuration of a light-emitting element 1 according to a first embodiment.

As illustrated in FIG. 1, the light-emitting element 1 includes: an anode 2; a cathode 6 disposed across from the anode 2; and a light-emitting layer 4 between the anode 2 and the cathode 6.

This embodiment exemplifies a case where the light-emitting element 1 includes a hole transport layer 3 between the anode 2 and the light-emitting layer 4. However, this embodiment shall not be limited to such a case. For example, the light-emitting element 1 may further include a not-shown hole injection layer. Between the anode 2 and the light-emitting layer 4, the hole injection layer and the hole transport layer 3 may be provided in the stated order from toward the anode 2. Furthermore, the hole transport layer 3 may be replaced with the hole injection layer, and the hole transport layer 3 and the hole injection layer may be omitted as appropriate.

Moreover, this embodiment exemplifies a case where the light-emitting element 1 includes an electron transport layer 5 between the light-emitting layer 4 and the cathode 6. However, this embodiment shall not be limited to such a case. For example, the light-emitting element 1 may further include a not-shown electron injection layer. Between the light-emitting layer 4 and the cathode 6, the electron transport layer 5 and the electron injection layer may be provided in the stated order from toward the light-light-emitting layer 4. Furthermore, the electron transport layer 5 may be replaced with the electron injection layer, and the electron transport layer 5 and the electron injection layer may be omitted as appropriate.

FIG. 2 is a view of a schematic configuration of the light-emitting layer 4 included in the light-emitting element 1 according to the first embodiment.

As illustrated in FIG. 2, the light-emitting layer 4 includes: quantum dots 7 each including a core 7C and a shell 7S coating the core 7C and containing a metal chalcogenide compound; and a plurality of spacer particles 8. In the light-emitting layer 4, holes transported from the anode 2 and electrons transported from the cathode 6 recombine together, so that the light-emitting layer 4 emits light.

This embodiment exemplifies a case where the whole shell 7S is made of the metal chalcogenide compound. However, this embodiment shall not be limited to such a case. For example, the shell 7S may be made of a plurality of layers, and, among the plurality of layers, the outermost layer may contain the metal chalcogenide compound. Moreover, as will be described later, the whole shell 7S may be made of a metal chalcogenide complex. If the shell 7S is made of a plurality of layers, the outermost layer among the plurality of layers may contain the metal chalcogenide complex. For example, the shell 7S may include: an inner shell coating the core 7C and containing a semiconductor material; and an outer shell containing either a metal chalcogenide complex or a metal chalcogenide compound.

As can be seen, in this embodiment, each of the quantum dots 7 includes: the core 7; and the shell 7S coating the core 7C and having an outermost layer containing either a metal chalcogenide complex 7L or a metal chalcogenide compound. Hence, compared with quantum dots having organic ligands, namely an insulating organic substance, bonding thereto, the quantum dots 7 can improve electrical conductivity in the quantum dot layer. Such a feature can reduce the driving voltage of the light-emitting element 1. Moreover, compared with quantum dots having organic ligands, namely an organic substance, bonding thereto, the quantum dots 7 do not contain an organic substance prone to deterioration by heat and light. Such a feature can provide the light-emitting element 1 with high reliability. Furthermore, in the case of the organic ligands, each of the ligands simply bonds independently to the surface of the quantum dots, such that the organic ligands are likely to come off while the light-emitting element is driving. Thus, high reliability is not expected. However, the shell 7S contains a metal chalcogenide compound made of complexes originally bonding as ligands, and reacting and recombining together. The shell 7S is a thin film made of the metal chalcogenide compound and shaped to coat the core 7C. Such a feature keeps the shell 7S from coming off while the light-emitting element 1 is driving, thereby making it possible to provide the light-emitting element 1 with high reliability. In addition, thanks to such a feature, the light-emitting layer does not contain a ligand material acting as a barrier to injection of the charges. Hence, the light-emitting element 1 can operate on a lower voltage and achieve even higher reliability.

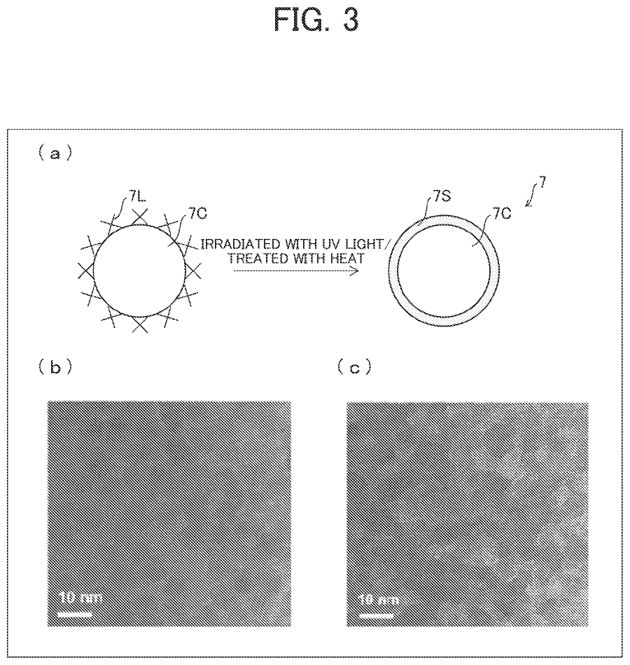

FIG. 3(a) is a view of a schematic configuration of a quantum dot, before and after irradiated with a UV light or treated with heat, contained in the light-emitting layer 4 included in the light-emitting element 1 of the first embodiment. FIG. 3(b) is a TEM image of quantum dots before irradiated with a UV light or treated with heat. FIG. 3(c) is a TEM image of quantum dots after irradiated with a UV light or treated with heat. Note that FIG. 3(a), FIG. 3(b), and FIG. 3(c) are derived from a non-patent document [Sci. Adv. 2019, 5, eaax801].

This embodiment exemplifies a case where the quantum dot 7 includes the shell 7S and the core 7C. The shell 7S is formed of the metal chalcogenide complex 7L bonding to the core 7C. The metal chalcogenide complex 7L is at least irradiated with an ultraviolet (UV) light or heated (treated with heat), and chemically altered to be electrically neutral and cured to form the shell 7S. However, the quantum dot 7 shall not be limited to such a case. For example, the quantum dot may include the core 7C and the metal chalcogenide complex 7L bonding to the core 7C, and the metal chalcogenide complex 7L bonding to the core 7C may be neither irradiated with an ultraviolet light nor treated with heat to be cured. In such a case, the metal chalcogenide complex 7L bonding to the core 7C serves as a shell. Moreover, the quantum dot may include: the core 7C; and a shell containing a metal chalcogenide compound coating the core 7C and the metal chalcogenide complex 7L bonding to the core 7C.

As seen in FIG. 3(b), if each of the quantum dots includes the core 7C and the metal chalcogenide complex 7L bonding to the core 7C, and the metal chalcogenide complex 7L bonding to the core 7C is neither irradiated with an ultraviolet light nor treated with heat to be cured, FIG. 3(b) shows that a distance between the quantum dots is shorter than a distance (approximately 2 nm) between quantum dots each including a core modified with a typical organic ligand.

Furthermore, as illustrated in FIG. 3(c), the metal chalcogenide complex 7L, bonding to the core 7C, is at least irradiated with an UV light or heated, and chemically altered sufficiently and cured as the shell. The quantum dots 7, each including the core 7C and the shell 7S coating the core 7C and containing the metal chalcogenide compound, are spaced apart at shorter distances than the quantum dots illustrated in FIG. 3(b) are.

As described above, in the case where the shell is the metal chalcogenide complex 7L boding to the core 7C, even if the shell 7S contains any of the metal chalcogenide compound coating the core 7C or of the metal chalcogenide compound and the metal chalcogenide complex 7L, a distance between the quantum dots is shorter than a distance between quantum dots modified with typical organic ligands.

It is known that the Foerster resonance energy transfer (FRET) efficiency (E), which is one factor causing a decrease in the light emission efficiency, is expressed by the following Equation (1), where “r” is the distance between the cores of quantum dots.

$$\begin{matrix}[ Math . 1 ] & \\ E = \frac{{R}_{0}^{6}}{{R}_{0}^{6} + {r}^{6}} & Equation 1\end{matrix}$$

In the above Equation (1), R₀, which is referred to as the Forster distance, is a distance between cores whose FRET efficiency (E) is 50%.

As described above, if the distance between the quantum dots; that is, the distance “r” between the cores of the quantum dots, is short, the Foerster resonance energy transfer (FRET) efficiency (E) increases, and there is a concern that the light emission efficiency decreases because of the Foerster resonance energy transfer (FRET).

Moreover, as described above, if the shells to be used contain either the metal chalcogenide compound or the metal chalcogenide complex 7L, the cores come into contact with one another through the metal chalcogenide with low electrical resistance. This inevitably causes a leak of a current in the light-emitting layer. The current leak interferes injection of carriers into the cores of the quantum dots, developing a problem of hindering improvement in light emission efficiency.

Hence, in this embodiment, as shown in FIG. 2, the light-emitting layer 4 includes the plurality of spacer particles 8. Because the light-emitting layer 4 includes the plurality of spacer particles 8, the light-emitting layer 4 can be formed to include clearance to provide a distance between at least two quantum dots included in the plurality of quantum dots 7 and positioned next to each other.

As can be seen, the clearance, formed with the spacer particles 8 and separating the quantum dots 7 from one another, can increase a distance between the quantum dots 7; that is, the distance r between the cores of the quantum dots. In the light-emitting element 1 including the light-emitting layer, such a feature can reduce the Foerster resonance energy transfer (FRET) and a leak of a current in the light-emitting layer 4. Hence, the light-emitting element 1 can improve light emission efficiency.

The spacer particles 8 may be an organic material, an inorganic material, or an inorganic-organic hybrid material as long as the spacer particles 8 can form clearance to provide a distance between the quantum dots 7. This embodiment exemplifies a case where the spacer particles 8 are formed of CdSe. However, this embodiment shall not be limited to such a case. As will be described later, the spacer particles 8 may be formed of a core material. Note that a preferable material, characteristic, and size of the spacer particles 8, as well as a preferable amount of the spacer particles 8 to be mixed, will be described later.

The core (a first core) 7C preferably contains one or a plurality of semiconductor materials selected from the group consisting of, for example, Cd, S, Te, Se, Zn, In, N, P, As, Sb, Al, Ga, Pb, Si, Ge, Mg, and a compound of these materials.

The core 7C preferably contains one or more selected from the group consisting of, for example, CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, and SiGe. In order for the light-emitting layer 4 containing the quantum dots 7 to emit light in different colors using such core materials, the cores may be formed of a single material with different particle sizes. For example, cores having the largest particle size may be used for a light-emitting layer that emits a red light. Cores having the smallest particle size may be used for a light-emitting layer that emits a blue light. Cores having a particle size between the particle sizes of the cores used for the light-emitting layer that emits the red light and for the light-emitting layer that emits the blue light may be used for a light-emitting layer that emits a green light. Moreover, in order for the light-emitting layer 4 containing the quantum dots 7 to emit light in different colors, the cores may be formed of different materials.

Either the metal chalcogenide complex 7L or the metal chalcogenide compound preferably contains at least one element selected from the group consisting of, for example, S, Se, and Te, and at least one element selected from the group consisting of, for example, Sn, In, Ga, and Sb. When these materials are used, and when metal chalcogenide complex ligands are at least irradiated with an ultraviolet (UV) light or heated, the metal chalcogenide complex ligands can be chemically altered to the metal chalcogenide compound that is stable and electrically neutral. Hence, the shells are successfully cured.

The metal chalcogenide compound preferably contains at least one selected from the group consisting of, for example, SnS₂, SnSe₂, In₂Se₃, In₂Te₃, Ga₂Se₃, Sb₂Se₃, and Sb₂Te₃.

The metal chalcogenide complex preferably contains at least one selected from the group consisting of, for example, Sn₂Se₆⁴⁻, Sn₂Se₆⁴⁻, In₂Se₄²⁻, In₂Te₄²⁻, Ga₂Se₄²⁻, Sb₂Se₄²⁻, and Sb₂Te₄²⁻.

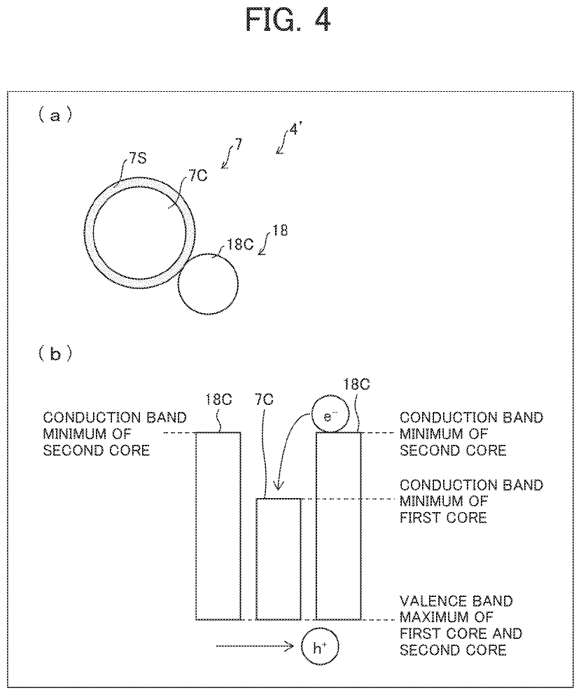

FIG. 4(a) is a view of a schematic configuration of a light-emitting layer 4′ included in a modification of the light-emitting element according to the first embodiment. FIG. 4(b) is a schematic band diagram of the light-emitting layer 4′ included in the modification of the light-emitting element according to the first embodiment.

As illustrated in FIG. 4(a), the light-emitting layer 4′ includes: the quantum dots 7 each containing the core 7C and the shell 7S coating the core 7C and containing a metal chalcogenide compound; and a plurality of spacer particles 18.

Each of the plurality of spacer particles 18 includes a core (a second core) 18C.

For example, a non-patent document [Adv. Optical Mater. 2020, 8, 1902092] discloses that red light-emitting quantum dots are mixed with blue light-emitting quantum dots including cores larger in bandgap than cores included in the red light-emitting quantum dots. The document reports that the mixture can increase an average distance between the red light-emitting quantum dots, and reduce a decrease in light emission efficiency.

Thus, the core (the second core) 18C preferably contains a material larger in bandgap than the material of the core (first core) 7C.

As described above, in the case where the shell is the metal chalcogenide complex 7L boding to the core 7C, even if the shell 7S contains any of the metal chalcogenide compound coating the core 7C or of the metal chalcogenide compound and the metal chalcogenide complex 7L, a distance between the quantum dots is shorter than a distance between quantum dots modified with typical organic ligands.

Because the light-emitting layer 4′ includes the plurality of spacer particles 18, the light-emitting layer 4′ can be formed to include clearance to provide a distance at least between at least two quantum dots included in the plurality of quantum dots 7 and positioned next to each other. Moreover, the clearance is provided between at least two spacer particles included in the spacer particles 18 and positioned next to each other. Such a feature can reduce a current flowing not through the quantum dots 7 but only through the spacer particles 18.

As can be seen, the clearance, formed with the spacer particles 18 and separating the quantum dots 7 from one another, can increase a distance between the quantum dots 7; that is, the distance “r” between the cores of the quantum dots. In the light-emitting element including the light-emitting layer 4′, such a feature can reduce the Foerster resonance energy transfer (FRET) and a leak of a current in the light-emitting layer 4′. Hence, the light-emitting element can improve light emission efficiency.

The core (the second core) 18C preferably contains one or a plurality of semiconductor materials selected from the group consisting of, for example, Cd, S, Te, Se, Zn, In, N, P, As, Sb, Al, Ga, Pb, Si, Ge, Mg, and a compound of these materials.

The core 18C preferably contains one or more selected from the group consisting of, for example, CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, and SiGe.

Different carrier transport techniques are used for a light-emitting layer containing quantum dots with organic ligands bonding thereto and the light-emitting layers 4 and 4′ containing the quantum dots 7 each including: the core 7C; and the shell 7S coating the core 7C and having an outermost layer containing either the metal chalcogenide complex 7L or the metal chalcogenide compound. There are two types of carrier movement in the light-emitting layer described below, and, in an actual light-emitting layer, these two types are combined at certain proportions to determine how to transport the carriers. The first carrier transport technique is hopping conduction. The hopping conduction exhibits equal transportation capability between the electrons and the holes, and the transportation of the electrons and the holes is not affected by the mobility of the carriers inside the quantum dots. The second carrier transport technique is band conduction. The band conduction exhibits different transportation capability between the electrons and the holes (typically, the mobility of the holes is lower than the mobility of the electrons), and the transportation of the electrons and the holes is affected by the mobility of the carriers inside the quantum dots.

In a light-emitting layer containing quantum dots with organic ligands bonding thereto, the organic ligands are insulative and the quantum dots are greatly distant from each other. Hence, in transporting the carriers, the hopping conduction is probably rate-limiting.

Meanwhile, the light-emitting layers 4 and 4′ contain the quantum dots 7 each including: the core 7C; and the shell 7S coating the core 7C and having an outermost layer containing either the metal chalcogenide complex 7L or the metal chalcogenide compound. As to the light-emitting layers 4 and 4′, in transporting the carries, the band conduction is probably rate-limiting.

For example, a non-patent document [12 Jun. 2009 VOL 324 SCIENCE] discloses that an Au particle film with organic ligands bonding thereto has an electrical conductivity of approximately up to 10⁻⁹ Scm⁻¹, whereas, an Au particle film whose ligands are substituted with Sn₂S₆⁴⁻ ligands has an electrical conductivity of approximately up to 200 Scm⁻¹, which is the 11th power of the electrical conductivity of the former Au particle film. This is probably because, in the Au particle film with the Sn₂S₆⁴⁻ ligands bonding thereto, the Au particles are positioned significantly closer to each other at a short distance, and the barrier formed by the organic ligands; namely, an insulator, is removed. As to the carrier transport technique of the Au particle film with the Sn₂S₆⁴⁻ bonding thereto, the resistance due to the hopping conduction is negligibly small. Thus, the band conduction is probably rate-limiting

As can be seen in the Au particle film with the Sn₂S₆⁴⁻ ligands bonding thereto, as to the carrier transportation technique of the light-emitting layers 4 and 4′ containing the quantum dots 7 each including: the core 7C; and the shell 7S coating the core 7C and having an outermost layer containing either the metal chalcogenide complex 7L or the metal chalcogenide compound, the band conduction is probably rate-limiting, and the holes are less likely to be conducted than the electrons are. As a result, the light-emitting layers 4 and 4′ exhibit an imbalance in the mobility of positive and negative carriers. Since the mobility of the electrons is higher than the mobility of the holes in a semiconductor to be typically used as a core material, the mobility of the electrons is higher than the mobility of the holes in the light-emitting layers 4 and 4′.

In such a case, recombination of the electrons and the holes is likely to occur at the interface between the light-emitting layers 4 and 4′ and the hole transport layer 3, and the electrons inevitably flow into the hole transport layer 3; that is, a current leak occurs. The leak of the current could cause a decrease in light emission efficiency. In addition, imbalance of the carriers occurs in the quantum dots, and the Auger recombination is likely to reduce light emission efficiency. In order to prevent the reduction in light-emission efficiency, the mobility of the electrons alone needs to be reduced.

Hence, in order to reduce the mobility of the electrons alone in the light-emitting layer 4′, as illustrated in FIG. 4(b), the cores (the first cores) 7C are mixed with the cores (the second cores) 18C whose valence band maximum (VBM) is equal to the VBM of the cores (the first cores) 7C and whose conduction band minimum (CBM) is lower than the CBM of the cores (the first cores) 7C. Thanks to the mixture, in terms of band level, the electrons alone are likely to be trapped to the conduction body maximum of the first cores having a deep level trap. Such a feature can prevent the electrons alone from moving. This is because, as illustrated in FIG. 4(b), an energy barrier exists in the injection of electrons from the core 7C to the core 18C.

In order to most readily prevent the electrons alone from moving in terms of band level as described above, the cores 18C may be made of the same material as the material of the cores 7C, and may be formed smaller in particle size than the cores 7C. This is because a variation in which the CBM becomes shallower is larger than a variation in which the VBM becomes deeper thanks to the quantum effect caused when the quantum dots are downsized for a material to be used for light-emitting quantum dots.

Note that if the electrons alone are kept from moving in terms of band level as described above, the cores 18C and the cores 7C may be made of different materials, and the cores 18C may be formed as large in particle size as the cores 7C or larger.

The cores 18C preferably have a bandgap of 3 eV or more and 6 eV or less. The cores 18C having a bandgap in such a range are used in appropriate combination with the cores 7C, thereby making it possible to keep the cores 18C from unnecessarily emitting light.

Meanwhile, the cores 7C may have a first peak emission wavelength, and the cores 18C may have a second peak emission wavelength shorter than the first peak emission wavelength. Moreover, the second peak emission wavelength may be 480 nm or less. Thanks to such a feature, the light-emitting element allows the cores 7C and the cores 18C to emit light in different colors.

Note that, each of the spacer particles 18 may include: the core 18C; and a not-shown shell coating the core 18C and having an outermost layer containing either a metal chalcogenide complex or a metal chalcogenide compound.

Note that, the spacer particle 18 may include: the core 18C; a not-shown shell coating the core 18; and an organic ligand bonding to the shell.

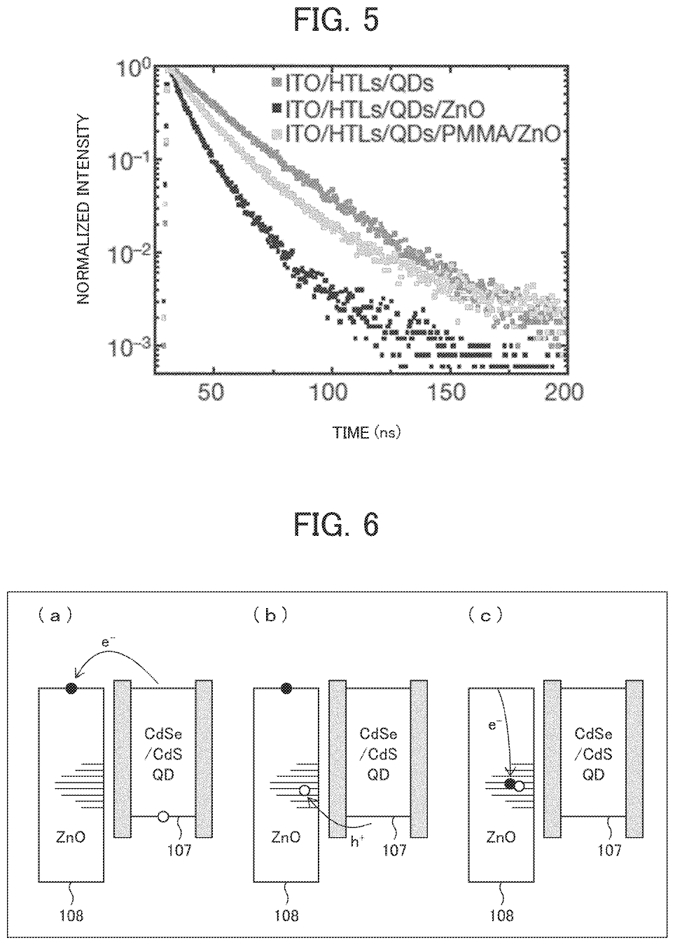

FIG. 5 is a graph showing preferable materials of the spacer particles 8 and 18.

FIG. 6(a), FIG. 6(b), and FIG. 6(c) are diagrams showing preferable materials of the spacer particles 8 and 18.

There is a desirable condition for the kinds of the spacer particles 18.

FIG. 5 is data comparing photoexcited emission lifetimes among: a case where a hole transport layer is stacked on an ITO electrode and a quantum dot layer (QDs) alone is stacked on the hole transport layer; a case where a quantum dot layer (QDs) and ZnO as an n-type semiconductor are stacked in direct contact with each other; and a case where PMMA as an organic insulator is provided between a quantum dot layer (QDs) and ZnO as an n-type semiconductor (Source: Non-Patent Document [96 Nature Vol 515, 6 Nov. 2014]).

As seen in FIG. 5, in comparison between the case where the quantum dot layer (QDs) alone is stacked and the case where the quantum dot layer (QDs) and ZnO as an n-type semiconductor are in direct contact with each other, the photoexcited emission lifetime in the latter case is significantly short, whereas, in the case where PMMA as an organic insulator is provided between the quantum dot layer (QDs) and ZnO as an n-type semiconductor, a decrease in emission lifetime is curbed compared with the case where ZnO is stacked directly on the quantum dot layer (QDs).

As shown in FIG. 6(a), FIG. 6(b), and FIG. 6(c), when a quantum dot layer 107 and a ZnO 108, which is an n-type semiconductor, are in direct contact with each other, the reason why the photoexcitation emission lifetime is shortest is that in the case of the ZnO 108, an oxygen defect is likely to occur and a level is observed between bands, so that excitons of the quantum dot 107 are unintentionally recombined through the level. Such a phenomenon probably occurs not only in ZnO but also in an artificially doped semiconductor material and a semiconductor that is likely to contain lattice defects.

Meanwhile, in the case where PMMA as an organic insulator is provided between the quantum dot layer (QDs) and ZnO as an n-type semiconductor, PMMA provides a distance between ZnO and the quantum dots. The distance reduces a flow of the excitons from the quantum dot layer (QDs) to ZnO and non-light-emitting recombination. As a result, the photoexcitation emission lifetime is increased. Hence, it is not preferable that ZnO and a doped semiconductor containing a large number of defect levels are found near the quantum dots.

As can be seen, the spacer particles 8 and 18 are desirably intrinsic semiconductors that are not doped and less likely to cause defects. Candidates of these intrinsic semiconductors desirably include CdSe, Cds, ZnS, ZnSe, and InP, which are used as core materials and shell materials of quantum dots.

A non-patent document [634 Nature Vol. 575, 28 Nov. 2019] reports that when a distance between the surface of a quantum dot and the core surface of an adjacent quantum dot is approximately 9 nm, the FRET efficiency (E) is 6% or less and the FRET is successfully reduced. Typically, the shell of a quantum dot has a thickness of approximately 2 to 3.5 nm. Hence, in order to reduce the FRET efficiency (E), the distance between the surfaces of adjacent quantum dots has to be left at least 2 nm or more. Hence, the spacer particles 8 and 18 preferably have an average particle size of 2 nm or more and 50 nm or less.

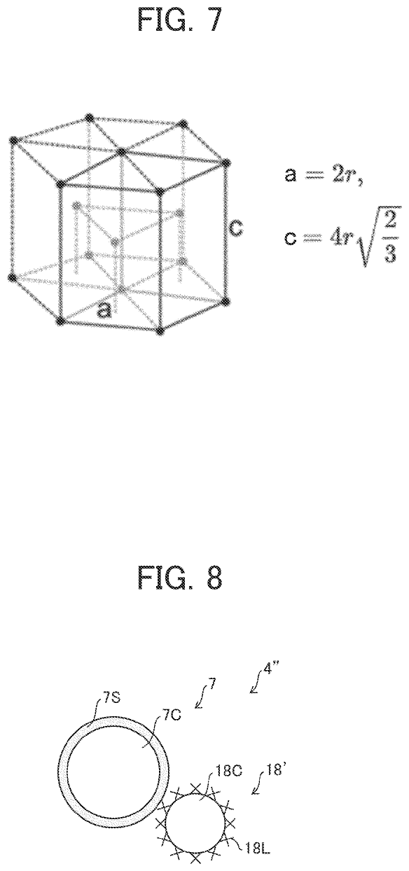

FIG. 7 is a view showing a preferable volume ratio of the spacer particles 8 and 18 to the light-emitting layers 4 and 4′ included in the light-emitting element according to the first embodiment.

As illustrated in FIG. 7, when the quantum dots 7 (lattice points in FIG. 7) are stacked in a hexagonal close-packed structure, a side “a” and a height “c” of the bottom surface of the hexagonal close-packed structure are represented as illustrated in FIG. 7. Then, an atomic packing factor APF is expressed by Equation (2) below:

$$\begin{matrix}[ Math . 2 ] & \\ APF = \frac{{N}_{atoms} {V}_{atom}}{{V}_{crystal}} = \frac{6 ( 4 / 3 ) π {r}^{3}}{[ ( 3 \sqrt{3} ) / 2 ] {a}^{2} c} & Equation 2\end{matrix}$$

In FIG. 7 and Equation 2, the sign “r” denotes a radius of a quantum dot 7.

When one side “a” and the height “c” of the bottom surface of the hexagonal close-packed structure illustrated in FIG. 7 are substituted into above Equation (2) as they are, the atomic packing factor APF is approximately 74%.

Considered next is a case where spacer particles are mixed, and the quantum dots 7 are spaced apart from one another at sufficient distances to reduce the FRET. A quantum dot 7 has a diameter of approximately 11 nm ((a core radius of 1.94 nm+a shell thickness of 3.46 nm)×2) and a distance kept by the organic ligands and provided between the quantum dots is approximately 2 nm, with reference to the high-efficiency quantum dots (QD-3R) in Extended Data Table 3 cited in a non-patent document [634 Nature Vol 575, 28 Nov. 2019].

With reference to the above numerical values, the atomic packing factor APF is calculated where the quantum dots 7 having a diameter of 11 nm are found at the lattice points of the hexagonal close-packed structure, and a distance between the centers of the quantum dots 7 is 13 nm. The calculated atomic packing factor APF is approximately 44.9%.

Here, considered is a case where a distance between the surfaces of the quantum dots 7 which is provided by the ligands is set to 2 nm by the spacer particles. If the particle size of the spacer particles 8 and 18 is sufficiently smaller than the particle size of the quantum dots 7, it can be approximately understood that a void portion with which no quantum dots 7 are filled is tightly filled with the spacer particles 8 and 18. That is, in such a case, it can be said that the spacer particles 8 and 18 having a volume ratio of approximately 55% are required in order to leave a distance of 2 nm between the quantum dots 7 having a diameter of 11 nm (1 (a volume ratio of the light-emitting layer)−0.45 (a volume ratio of the quantum dots 7)=0.55 (a volume ratio of the spacer particles 8 and 18)).

As can be seen, the particle size of the spacer particles 8 and 18 is preferably smaller than the particle size of the quantum dots 7, and, more preferably, smaller than the particle size of the cores 7C.

Moreover, the volume ratio of the spacer particles 8 and 18 to the light-emitting layers 4 and 4′ is preferably 55% or more and 90% or less.

FIG. 8 is a view of a schematic configuration of a light-emitting layer 4″ included in another modification of the light-emitting element according to the first embodiment.

As illustrated in FIG. 8, the light-emitting layer 4″ includes: the quantum dots 7 each containing the core 7C and the shell 7S coating the core 7C and containing a metal chalcogenide compound; and a plurality of spacer particles 18′.

FIG. 8 exemplifies a case where each of the plurality of spacer particles 18′ includes the core 18C; and an organic ligand 18L bonding to the core 18C. However, the spacer particles 18′ shall not be limited to such a case. For example, the plurality of the spacer particles 18′ may each include: the core 18C; a shell coating the core 18; and the organic ligand 18L bonding to the shell.

Note that if the spacer particles 18′ are the spacer particles 8 shown in FIG. 2, the spacer particles 18′ contain organic ligands bonding to the spacer particles 8.

As can be seen, because the spacer particles include the organic ligands, the light-emitting layer can be formed to include clearance to provide a further distance between the quantum dots 7.

The thickness of each of the light-emitting layers 4, 4′ and 4″ shall not be limited to a particular thickness as long as the thickness can provide room for the electrons and the holes to recombine together to emit light. For example, the thickness may be approximately 1 to 200 nm.

A material to be used for the hole transport layer 3 illustrated in FIG. 1 shall not be limited to a particular material as long as the material is a hole transporting material capable of transporting the holes injected from the anode 2 into the light-emitting layer 4. In particular, the hole transporting material preferably has a high hole mobility. Furthermore, the hole transporting material is preferably a material (an electron blocking material) capable of preventing penetration of electrons moving from the cathode 6. Such a feature can increase efficiency in recombination of the holes and the electrons in the light-emitting layer 4.

Examples of the material to be used for the hole transport layer 3 include an arylamine derivative, an anthracene derivative, a carbazole derivative, a thiophene derivative, a fluorene derivative, a distyrylbenzene derivative, and a spiro compound. Moreover, the material to be used for the hole transport layer 4 is more preferably polyvinyl carbazole (PVK) or poly[(9,9-dioctylfluorenyl-2,7-diyl)-co-(4,4′-(N-(4-sec-butylphenyl))diphenylamine)] (TFB).

In addition, the hole transport layer 3 may be formed of an inorganic semiconductor material. Examples of the inorganic semiconductor material include a metal oxide (including a metal oxide semiconductor), a nitride semiconductor, an arsenide semiconductor, a halide semiconductor, and a pseudohalide semiconductor. If the hole transport layer 3 is formed of an inorganic semiconductor material, the inorganic semiconductor material may be doped with an acceptor impurity so that the hole transport layer 3 can exhibit a significant hole transporting capability.

If the hole transport layer 3 is formed first and then the light-emitting layer 4 is formed, the hole transport layer 3 is preferably formed of a metal oxide semiconductor, and the hole transport layer 3 formed of the metal oxide semiconductor is preferably in contact with the light-emitting layer 4. Such a feature can reduce damage including heat and light and given to the hole transport layer 3 in forming the light-emitting layer 4.

A material to be used for a not-shown hole injection layer shall not be limited to a particular material as long as the material is a hole injecting material capable of stably injecting the holes into the light-emitting layer 4. Examples of the hole injecting material include an arylamine derivative, a porphyrin derivative, a phthalocyanine derivative, a carbazole derivative, and conductive polymers such as a polyaniline derivative, a polythiophene derivative, and a polyphenylene vinylene derivative. Moreover, the material to be used for the hole injection layer 3 is preferably poly(3,4-ethylenedioxythiophene)-polystyrene sulfonic acid (PEDOT-PSS).

A thickness of the not-shown hole injection layer and a thickness of the hole transport layer 3 shall not be limited to particular thicknesses as long as the thicknesses can sufficiently exhibit capabilities to inject and transport the holes.

A material to be used for the electron transport layer 5 illustrated in FIG. 1 shall not be limited to a particular material as long as the material is an electron transporting material capable of transporting the electrons injected from the cathode 6 into the light-emitting layer 4. In particular, the electron transporting material preferably has a high electron mobility. Furthermore, the electron transporting material is preferably a material (a hole blocking material) capable of preventing penetration of holes moving from the anode 2. Such a feature can increase efficiency in recombination of the holes and the electrons in the light-emitting layer 4.

Examples of the electron transporting material include oxadiazoles, triazoles, phenanthrolines, a silole derivative, a cyclopentadiene derivative, an aluminum complex, a metal oxide (including a metal oxide semiconductors), a nitride semiconductor, and an arsenide semiconductor. Specific examples of the oxadiazole derivative include (2-(4-biphenylyl)-5-(4-tert-butylphenyl)-1,3,4-oxadiazole) (PBD). Specific examples of the phenanthrolines include bathocuproine (BCP) and bathophenanthroline (Bphen). Specific examples of the aluminum complex include a tris(8-quinolinol) aluminum complex (Alq3) and a bis(2-methyl-8-quinolato)(p-phenylphenolate) aluminum complex (Balq).

Examples of the metal oxide as the electron transporting material include ZnO, MgZnO, TiO₂, Ta₂O₃, SrTiO₃, and MgₓZn₁₋ₓO (where x is the ratio of Zn in ZnO replaced with Mg).

Furthermore, examples of the inorganic semiconductor material as the electron transporting material include a group II-VI semiconductor material and a group III-V semiconductor material. Examples of the group II-VI semiconductor material include ZnS, ZnSe, ZnTe, Cds, CdSe, CdTe, HgTe, and a mixed crystal of these materials, and examples of the group III-V semiconductor material include AlP, AlAs, AlN, AlSb, GaN, GaP, GaAs, GaSb, InP, InAs, InSb, InN, and a mixed crystal of these materials.

There is no problem as long as the semiconductor material is a native n-type semiconductor material. If necessary, the semiconductor material may contain a donor impurity.

The material to be used for the electron transport layer 5 is preferably MgₓZn₁₋ₓO. Ionization potential and electron affinity of MgₓZn₁₋ₓO can be adjusted when x is adjusted. Such a feature makes it possible to readily prepare an electron transport layer suitable to an emission wavelength of the QD emission layer.

Note that if the electron transport layer 5 is formed first and then the light-emitting layer 4 is formed, the electron transport layer 5 is preferably formed of a metal oxide semiconductor, and the electron transport layer 5 formed of the metal oxide semiconductor is preferably in contact with the light-emitting layer 4. Such a feature can reduce damage including heat and light and given to the electron transport layer 5 in forming the light-emitting layer 4.

A material to be used for a not-shown electron injection layer shall not be limited to a particular material as long as the material is an electron injecting material capable of stably injecting the electrons into the light-emitting layer 4. Examples of the electron injecting material include: alkali metals or alkaline earth metals such as aluminum, strontium, calcium, lithium, cesium, magnesium oxide, aluminum oxide, strontium oxide, lithium oxide, lithium fluoride, magnesium fluoride, strontium fluoride, calcium fluoride, barium fluoride, cesium fluoride, sodium polymethylmethacrylate polystyrene sulfonate; oxides of alkali metals or alkaline earth metals; fluorides of alkali metals or alkaline earth metals, and organic complexes of alkali metals.

A thickness of the electron transport layer 5 and a thickness of the electron injection layer shall not be limited to particular thicknesses as long as the thicknesses can sufficiently exhibit capabilities to transport and inject the electrons.

A material to be used for the anode 2 illustrated in FIG. 1 is preferably a conductive material having a large work function so that anode 2 can readily inject the holes. Examples of the conductive material include: metals such as Au, Ta, W, Pt, Ni, Pd, Cr, Cu, Mo, alkali metals, and alkaline earth metals; oxides of these metals; Al alloys such as AlLi, AlCa, and AlMg, Mg alloys such as MgAg, Ni alloys, Cr alloys, alkali metal alloys, and alkaline earth metal alloys; inorganic oxides such as indium tin oxide (ITO), indium zinc oxide (IZO), zinc oxide (ZnO), and indium oxide; conductive polymers such as metal-doped polythiophene, polyaniline, polyacetylene, polyalkylthiophene derivatives, and polysilane derivatives; and α-Si and α-SiC. These conductive materials may be used alone or in combination of two or more. If two or more of these conductive materials are used, the materials may form respective layers to be stacked on top of another. Note that indium tin oxide (ITO) is used more preferably.

A material to be used for the cathode 6 illustrated in FIG. 1 is preferably a conductive material having a small work function so that cathode 6 can readily inject the electrons. In particular, the material is preferably a metal material. The metal material has an advantageous effect of exhibiting high conductivity. Examples of the metal material include: magnesium alloys such as MgAg; aluminum alloys such as AlLi, AlCa, and AlMg; alkaline earth metals such as Li, Cs, Ba, Sr. and Ca; and alloys of the alkali metals. Note that Al or an Al alloy is used more preferably. Al or an Al alloy is versatile as an electrode and relatively inexpensive, thereby making it possible to reduce manufacturing costs of the light-emitting element 1.

Of the anode 2 and the cathode 6, the electrode provided toward a light releasing face needs to be transparent. Meanwhile, the electrode across from the light releasing face may be either transparent or non-transparent. Moreover, the anode 2 and the cathode 6 are preferably low in resistance, and typically made of a metal material: that is, a conductive material. The anode 2 and the cathode 6 may be made of an organic compound or inorganic compound.

A method for manufacturing the light-emitting element 1 illustrated in FIG. 1 includes, for example: a step of forming a multilayer stack including the anode (the first electrode) 2 and the hole transport layer 3 or a step of forming a multilayer stack including the cathode (the first electrode) 6 and the electron transport layer 5; a step of coating the multilayer stack with a solution including the plurality of quantum dots 7 and the spacer particles 8 and 18, the plurality of quantum dots 7 each including a core 7C and a shell 7S coating the core 7C and having an outermost layer containing either a metal chalcogenide complex or a metal chalcogenide compound; and a step of at least irradiating the solution with an ultraviolet light or heating the solution, and of forming the light-emitting layer 4 including clearance to provide a distance between at least two quantum dots 7 included in the plurality of quantum dots 7 and positioned next to each other.

Note that described below as an example is how to prepare the solution including the plurality of quantum dots 7 and the spacer particles 8 and 18, the plurality of quantum dots 7 each including a core 7C and a shell 7S coating the core 7C and having an outermost layer containing a metal chalcogenide complex or a metal chalcogenide compound.

First, a five-milligram metal chalcogenide ligand material such as (CH₃NH₃)₄Sn₂S₆ capable of curing the shell is weighed into, for example, a cleaned screw tube. After that, the metal chalcogenide ligand material is dissolved in a mixed solution of 2 ml of dimethyl sulfoxide (DMSO) and 1 ml of ethanolamine (EA). Then, for example, a dispersion solution in which the cores 7C are dispersed in hexane or octane is put into the mixed solution in which the metal chalcogenide ligand material is melted, and stirred with a stirrer at about 400 rpm for 3 to 4 hours. The mixed solution, in which the dispersion solution and the metal chalcogenide ligand material are dissolved, separates into two layers. The mixed solution in which the metal chalcogenide ligand material is dissolved is the lower layer and the dispersion solution is the upper layer. Then, when the metal chalcogenide ligands are completely substituted, the color of the upper layer (hexane or octane) transfers to the lower layer (the mixed solution of DMSO and EA), and the upper layer becomes transparent. After that, the liquid in the upper layer is removed, and the liquid in the lower layer is washed several times with hexane. Then, the cores 7C with the metal chalcogenide ligands bonding thereto in the lower layer are taken out. Acetonitrile is added to the cores 7C so that the cores 7C are precipitated. Acetonitrile is centrifuged at 6000 rpm for 10 minutes so that the cores 7C are completely precipitated. Then, the supernatant liquid is removed, and the cores 7C with the metal chalcogenide ligands bonding thereto are redispersed in a mixed solution of dimethyl sulfoxide (DMSO) and ethanolamine (EA). Finally, the redispersion solution, in which the cores 7C with the metal chalcogenide ligands bonding thereto are redispersed, and a dispersion solution, in which the spacer particles 8 or the cores 18C to serve as the spacer particles 18 are dispersed, are mixed together at any given ratio. Hence, a solution to coat a light-emitting layer can be obtained.

If the metal chalcogenide ligands have to be bonded to the surface of the cores 18C serving as the spacer particles 18, a redispersion solution of the cores 18C with the metal chalcogenide ligands bonding thereto may be prepared by the same technique as the technique of obtaining the redispersion solution of the cores 7C with the metal chalcogenide ligands boding thereto. After that, the redispersion solution, in which the cores 7C with the metal chalcogenide ligands bonding thereto, and the redispersion solution, in which the cores 18C with the metal chalcogenide ligands thereto, are mixed together at any given ratio. Hence, a solution to coat a light-emitting layer can be obtained.

Furthermore, if spacer particles 18′, which includes the organic ligands 18L bonding to the cores 18C illustrated in FIG. 8, are used, the redispersion solution, in which the cores 7C with the metal chalcogenide ligands bonding thereto, may be mixed with a dispersion liquid, which contains cores 18C with which the organic ligands 18L boding thereto, at any given ratio.

Moreover, for example, a non-patent document [12 Jun. 2009 VOL 324 SCIENCE] describes the use of hydrazine as a solvent. However, when hydrazine is used, the hydrazine inevitably remains in the quantum dot layer after film formation. Hydrazine is not preferable because strong reducibility of hydrazine corrodes quantum dots and other layers. Furthermore, since hydrazine has high hygroscopicity, a large amount of water molecules are contained in the light-emitting element depending on a process, which is not preferable from the viewpoint of long-term reliability.

In the above-described method for manufacturing the light-emitting element 1, a coating solution to be used preferably contains dimethyl sulfoxide (DMSO). In the case of dimethyl sulfoxide (DMSO), strong reducibility is not exhibited even when dimethyl sulfoxide (DMSO) remains in the quantum dots after film formation. Hence, the light-emitting element 1 can achieve long-term reliability.

Note that described below may be examples of a step of coating with the above coating solution and a step of irradiating the coating solution with an ultraviolet light, or of heating the coating solution, and forming the light-emitting layers 4, 4, and 4″ including clearance to provide a distance between at least two quantum dots 7 included in the plurality of quantum dots 7 and positioned next to each other.

The coating solution can be applied, for example, by a technique such as spin coating, dipping, or misting. After that, the applied solution is, for example, at least either irradiated with an ultraviolet light of 365 nm, or heated, to form the light-emitting layers 4, 4, and 4″. After that, if necessary, the light-emitting layers 4, 4, and 4″ are washed with a mixed solution of dimethyl sulfoxide (DMSO) and ethanolamine (EA).

As described above, if the shells are the metal chalcogenide complex 7L bonding to the cores 7C, the metal chalcogenide complex 7L does not have to be irradiated with the ultraviolet light or heated to form the shells.

In the first embodiment, the quantum dots include the cores and the shells coating the cores. Alternatively, it may also be described that the shells are provided to the surface of the cores. Moreover, a shell coats at least a portion of a core, and, preferably, the shell coats the entire core. If a cross-section of a quantum dot shows that the shell covers the core, it may be said that the shell covers the core.

### Second Embodiment

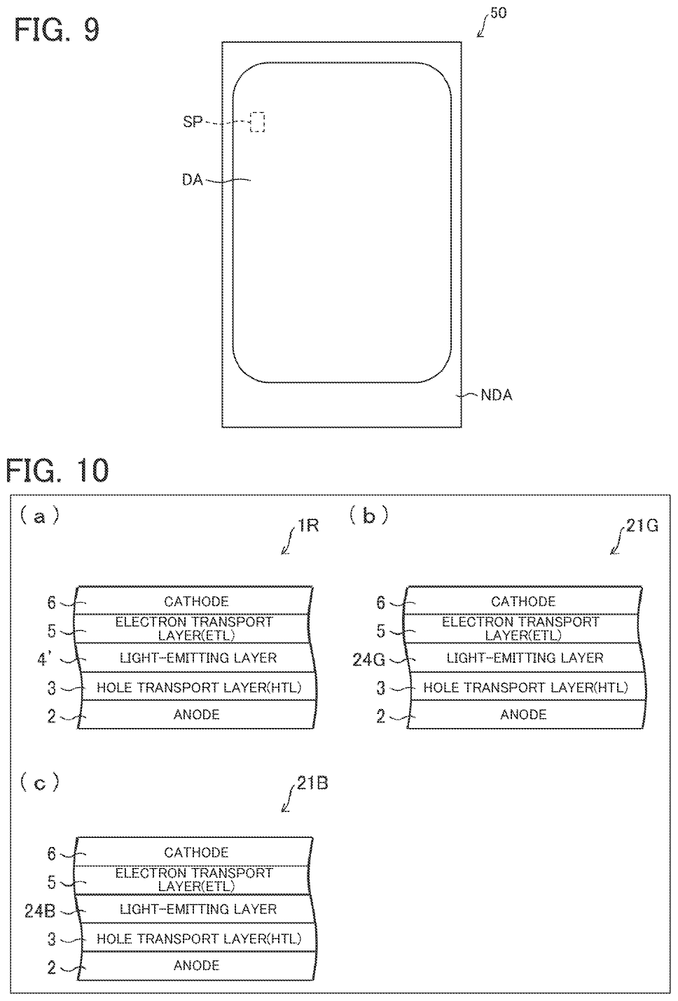

Described next is a second embodiment of the present invention, with reference to FIGS. 9 to 11. A display device 50 of this embodiment includes the light-emitting element described in the first embodiment as one of the subpixels included in one pixel. For convenience in description, like reference signs designate identical constituent features throughout the drawings between this embodiment and the first embodiment. These constituent features will not be elaborated upon.

FIG. 9 is a plan view of a schematic configuration of the display device 50 according to the second embodiment.

As illustrated in FIG. 9, the display device 50 includes a display region DA and a picture-frame region NDA. The display region DA includes a plurality of subpixels SP, and adjacent subpixels SP among the plurality of subpixels SP constitute one pixel of the display device 50.

FIG. 10(a) is a view of an example of a red light-emitting element 1R included in the display device 50. FIG. 10(b) is a view of an example of a green light-emitting element 21G included in the display device 50. FIG. 10(c) is a view of an example of a blue light-emitting element 21B included in the display device 50.

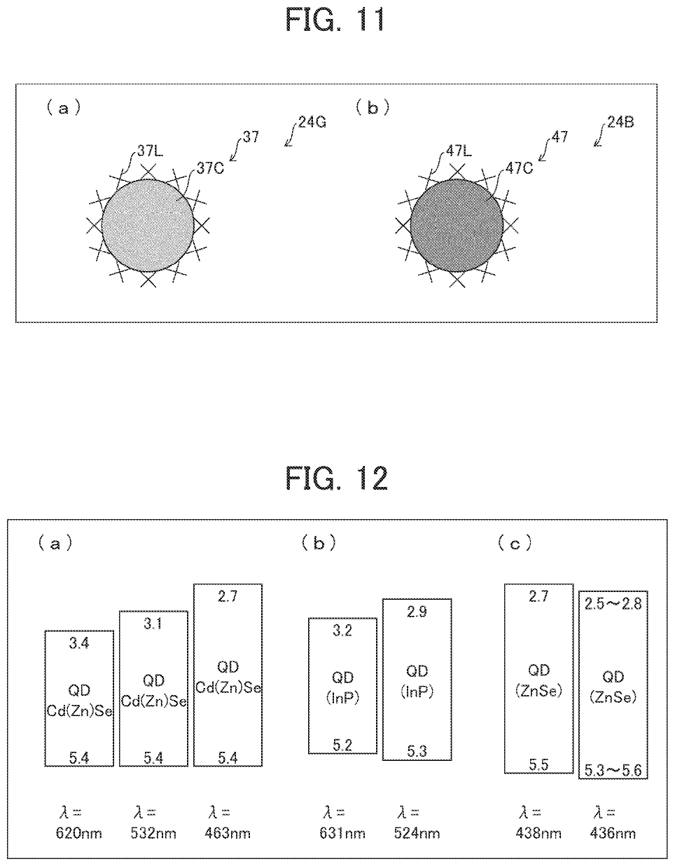

FIG. 11(a) is a view of a schematic configuration of a light-emitting layer 24G included in the green light-emitting element 21G illustrated in FIG. 10(b). FIG. 11(b) is a view of a schematic configuration of a light-emitting layer 24B included in the blue light-emitting element 21B illustrated in FIG. 10(c).

Typically, one pixel of a display device includes a red subpixel, a green subpixel, and a blue subpixel. The red subpixel includes a light-emitting element including a light-emitting layer that emits a red light. The green subpixel includes a light-emitting element including a light-emitting layer that emits a green light. The blue subpixel includes a light-emitting element including a light-emitting layer that emits a blue light.

The red light-emitting element 1R illustrated in FIG. 10(a) includes the light-emitting layer 4′ described in the first embodiment, and emits a red light. Note that the core 18C; that is, the spacer particle 18 included in the light-emitting layer 4′, is a core 47C contained in the light-emitting layer 24B included in the blue light-emitting element 21B illustrated in FIG. 10(c) and FIG. 11(b).

The green light-emitting element 21G illustrated in FIG. 10(b) includes the light-emitting layer 24G illustrated in FIG. 11(a), and emits a green light. As illustrated in FIG. 11(a), the light-emitting layer 24G contains cores 37C and ligands 37L. The light-emitting layer 24G contains a less amount of spacer particles than the light-emitting layer 4′ does. Moreover, the light-emitting layer 24G does not preferably contain spacer particles.

The blue light-emitting element 21B illustrated in FIG. 10(c) includes the light-emitting layer 24B illustrated in FIG. 11(b), and emits a blue light. As illustrated in FIG. 11(b), the light-emitting layer 24B contains cores 47C and ligands 47L. The light-emitting layer 24B contains a less amount of spacer particles than the light-emitting layer 4′ and the light-emitting layer 24G do. Moreover, the light-emitting layer 24B does not preferably contain spacer particles.

In this embodiment, the cores 7C contained in the light-emitting layer 4′ included in the red light-emitting element 1R, the cores 37C contained in the light-emitting layer 24G included in the green light-emitting element 21G, and the cores 47C contained in the light-emitting layer 24B included in the blue light-emitting element 21B are made of the same material with different particle sizes. For example, the cores 7C having the largest particle size can be used for the light-emitting layer 4′ that emits a red light. The cores 47C having the smallest particle size can be used for the light-emitting layer 24B that emits a blue light. The cores 37C having a particle size between the particle size of the cores 7C to be used for the light-emitting layer 4′ that emits the red light and the particle size of the cores 47C to be used for the light-mitting layer 24B that emits the blue light can be used for the light-emitting layer 24G that emits a green light. The cores 7C, 37C, and 47C shall not be limited to such examples, and may be formed of different materials.

This embodiment exemplifies a case where the spacer particles are contained only in the light-emitting layer 4′ of the red light-emitting element 1R. However, this embodiment shall not be limited to such a case. The spacer particles may be contained in the light-emitting layer of at least one of the red light-emitting layer, the green light-emitting layer, or the blue light-emitting layer.

Moreover, FIG. 11(a) exemplifies a case where the quantum dots 37 included in the light-emitting layer 24G each contains a core 37C and a ligand 37L. However, the quantum dots 37 shall not be limited to such a case. Each of the quantum dots 37 may contain the core 37C and a shell coating at least a part of the core 37C and having an outermost layer containing a metal chalcogenide complex or a metal chalcogenide compound.

Moreover, FIG. 11(b) exemplifies a case where the quantum dots 47 included in the light-emitting layer 24B each contains a core 47C and a ligand 47L. However, the quantum dots 47 shall not be limited to such a case. Each of the quantum dots 47 may contain the core 47C and a shell coating at least a part of the core 47C and having an outermost layer containing a metal chalcogenide complex or a metal chalcogenide compound.

### Third Embodiment

Described next is a third embodiment of the present invention, with reference to FIGS. 12 to 14. A display device of this embodiment differs from the display device 50 described in the second embodiment in that, in the former display device, all the subpixels constituting one pixel include the light-emitting element described in the first embodiment. Otherwise, the display device of this embodiment is the same as the display devices of the first and second embodiments. For convenience in description, like reference signs designate identical constituent features throughout the drawings between this embodiment and the first and second embodiments. These constituent features will not be elaborated upon.

FIG. 12(a) is a band diagram of a plurality of kinds of Cd cores having different peak emission wavelengths. FIG. 12(b) is a band diagram of a plurality of kinds of InP cores having different peak emission wavelengths. FIG. 12(c) is a band diagram of a plurality of kinds of ZnSe cores having different peak emission wavelengths.

FIG. 12(a) illustrates bandgaps of Cd (Cd(Zn)Se) cores having emission wavelength peaks λ of 620 nm, 532 nm, and 463 nm. FIG. 12(b) illustrates bandgaps of InP (InP) cores having emission wavelength peaks λ of 631 nm and 524 nm. FIG. 12(c) illustrates bandgaps of ZnSe (ZnSe) cores having emission wavelength peaks λ of 438 nm and 436 nm.

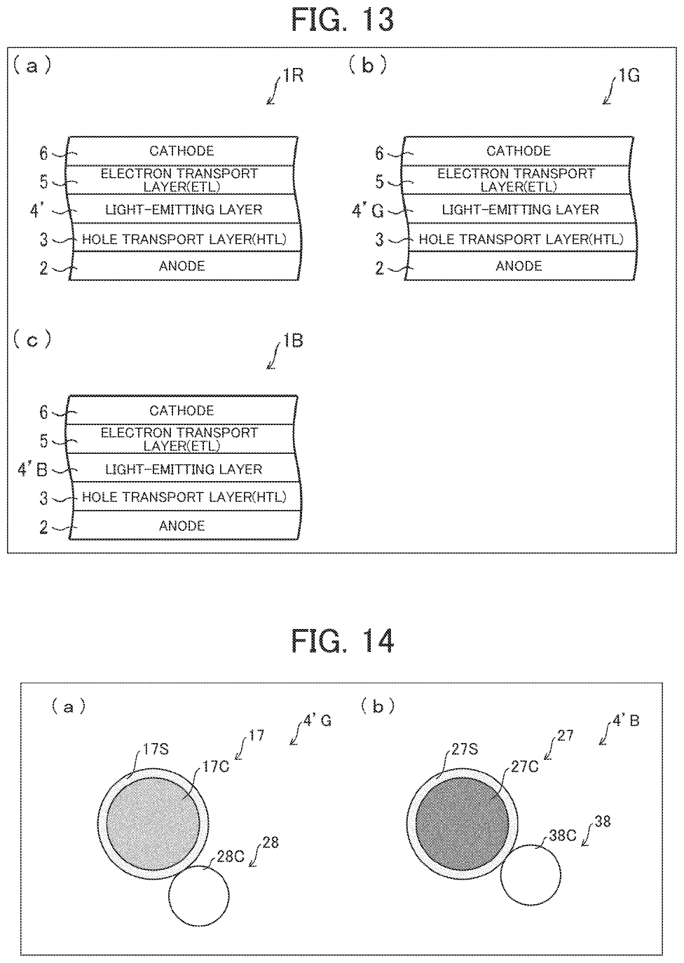

FIG. 13(a) is a view of an example of the red light-emitting element 1R included in the display device according to this embodiment. FIG. 13(b) is a view of an example of a green light-emitting element 1G included in the display device according to this embodiment. FIG. 13(c) is a view of an example of a blue light-emitting element 1B included in the display device according to this embodiment.

FIG. 14(a) is a view of a schematic configuration of a light-emitting layer 4G′ included in the green light-emitting element 1G illustrated in FIG. 13(b). FIG. 14(b) is a view of a schematic configuration of a light-emitting layer included in a blue light-emitting element 4′B illustrated in FIG. 13(c).

The red light-emitting element 1R illustrated in FIG. 13(a) includes the light-emitting layer 4′ described in the first embodiment, and emits a red light. Note that, contained in the light-emitting layer 4′, the cores 7C, and the cores 18C serving as the spacer particle 18, are formed of Cd(Zn)Se. The bandgap of each of the cores 7C in the red light-emitting element 1R is 2 eV as illustrated in FIG. 12(a). The bandgap of each of the cores 18C in the red light-emitting element 1R is 2.7 eV, which is, for example, 0.7 eV larger than the bandgap of the core 7C. The particle size of the core 18C is adjusted so that the bandgap of the core 18C is 2.7 eV.

The green light-emitting element 1G illustrated in FIG. 13(b) includes a light-emitting layer 4′G illustrated in FIG. 14(a), and emits a green light. As illustrated in FIG. 14(a), the light-emitting layer 4′G includes: quantum dots 17 each including a core 17C and a shell 17S coating the core 17C; and spacer particles 28 each including a core 28C. Note that, contained in the light-emitting layer 4′G, the cores 17C, and the cores 28C serving as the spacer particles 28, are formed of Cd(Zn)Se. The bandgap of each of the cores 17C in the green light-emitting element 1G is 2.3 eV as illustrated in FIG. 12(a). Note that the bandgap of each of the cores 28C in the green light-emitting element 1G is 3.0 eV, which is, for example, 0.7 eV larger than the bandgap of the core 17C. The particle size of the core 28C is adjusted so that the bandgap of the core 28C is 3.0 eV.

The blue light-emitting element 1B illustrated in FIG. 13(c) includes a light-emitting layer 4B′ illustrated in FIG. 14(b), and emits a blue light. As illustrated in FIG. 14(b), the light-emitting layer 4′B includes: quantum dots 27 each including a core 27C and a shell 27S coating the core 27C; and spacer particles 38 each including a core 38C. Note that, contained in the light-emitting layer 4′B, the cores 27C, and the cores 38C serving as the spacer particle 38, are formed of Cd(Zn)Se. The bandgap of each of the cores 27C in the blue light-emitting element 1B is 2.7 eV as illustrated in FIG. 12(a). Note that the bandgap of each of the cores 38C in the blue light-emitting element 1B is 3.4 eV, which is, for example, 0.7 eV larger than the bandgap of the core 27C. The particle size of the core 38C is adjusted so that the bandgap of the core 38C is 3.4 eV.

The core 18C whose bandgap is 2.4 eV is larger in particle size than the core 28C whose bandgap is 3.0 eV. The core 28C whose bandgap is 3.0 eV is larger in particle size than the core 38C whose bandgap is 3.4 eV

Note that the spacer particles 38 including the cores 38C included in the light-emitting layer 4′B of the blue light-emitting element 1B can be used for the light-emitting layer 4′ of the red light-emitting element 1R and the light-emitting layer 4′G of the green light-emitting element 1G; however, the problem is that the spacer particles 38 exhibit leakage reduction capability larger than necessary, and inevitably increase the drive voltage. This is because the charge injection barrier is higher as the bandgap of spacer particles is larger. Accordingly, transportation of the charges is difficult. Hence, as described in this embodiment, the size of the spacer particles is determined so that the particle size is greater in the order of the cores 18C, the cores 28C, and the cores 38C. Such a feature can reduce the risk that the leakage reduction capability is larger than necessity, and decrease a drive voltage.

In the step of manufacturing the display device of this embodiment, similar to the method described in the first embodiment, respective coating solutions are prepared for forming the light-emitting layer 4′ of the red light-emitting element 1R, the light-emitting layer 4′G of the green light-emitting element 1G, the light-emitting layer 4′B of the blue light-emitting element 1B. Then, first, one of the above three coating solutions is thoroughly applied by various wet film forming techniques (spin coating, bar coating, dip coating, flow coating, screen printing, and inkjet printing). After that, only a portion to form the light-emitting layer is irradiated with light and cured. Here, if necessary, the portion may be baked before and after the exposure to the light. Then, the portion is rinsed with dimethyl sulfoxide (DMSO), and a film of an unnecessary portion; that is, an uncured portion, is removed. After that, the remaining two coating solutions similarly form the light-emitting layers in different positions. Hence, the display device of the present embodiment is successfully manufactured.

### ADDITIONALLY REMARKS

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Moreover, the technical aspects disclosed in each embodiment may be combined to achieve a new technical feature.

### INDUSTRIAL APPLICABILITY

The present invention is applicable to a light-emitting element, a display device, and a light-emitting element manufacturing method.

### REFERENCE SIGNS LIST

1, 1R, 1G, and 1B Light-Emitting Element
2 Anode
3 Hole Transport Layer
4, 4′, 4′G, 4′B, and 4″ Light-Emitting Layer
5 Electron Transport Layer
6 Cathode
7, 17, and 27 Quantum Dots
7L Metal Chalcogenide Complex
7S, 17S, and 27S Shell
7C, 17C, and 27C First Core
8, 18, 18′, 28, and 38 Spacer Particle
18C, 28C, and 38C Second Core
18L Organic Ligand
21G and 21B Light-Emitting Element
24G and 24B Light-Emitting Layer
37C and 47C Core
37L and 47L Ligand
37 and 47 Quantum Dots
50 Display Device
h⁺ Holes
e⁻ Electrons
SP Subpixel
DA Display Region
NDA Picture-Frame Region

1. A light-emitting element, comprising:
a first electrode;
a second electrode disposed across from the first electrode; and
a first light-emitting layer disposed between the first electrode and the second electrode, and including a plurality of first quantum dots and a spacer particle, the plurality of first quantum dots each including a first core and a first shell coating the first core and having an outermost layer containing either a metal chalcogenide complex or a metal chalcogenide compound, wherein the spacer particle includes: a second core; and a second shell coating the second core and having an outermost layer containing either a metal chalcogenide complex or a metal chalcogenide compound.

2. (canceled)

3. The light-emitting element according to claim 1,
wherein the second core contains a material larger in bandgap than a material of the first core.

4. The light-emitting element according to claim 1,
wherein at least one of the first core or the second core contains one or more selected from the group consisting of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, and SiGe.

5. The light-emitting element according to claim 1,
wherein the second core has a bandgap of 3 eV or more and 6 eV or less.

6. The light-emitting element according to claim 1,
wherein the second core is smaller in particle size than the first core.

7. The light-emitting element according to claim 1,
wherein the first core has a first peak emission wavelength, and
the second core has a second peak emission wavelength shorter than the first peak emission wavelength.

8. The light-emitting element according to claim 7,
wherein the second peak emission wavelength is 480 nm or less.

9. The light-emitting element according to claim 1, further comprising
an organic ligand bonding to the spacer particle.

10. (canceled)

11. The light-emitting element according to claim 1,
wherein the second core contains a same material as a material contained in the first core.

12. The light-emitting element according to claim 1,
wherein the spacer particle is smaller in particle size than the first core.

13. The light-emitting element according to claim 1,
wherein the spacer particle has an average particle size of 2 nm or more and 50 nm or less.

14. The light-emitting element according to claim 1,
wherein the first shell includes:
an inner shell coating the first core and containing a semiconductor material; and
an outer shell containing either the metal chalcogenide complex or the metal chalcogenide compound.

15. The light-emitting element according to claim 1,
wherein either the metal chalcogenide complex or the metal chalcogenide compound contains at least one element selected from the group consisting of S, Se, and Te, and at least one element selected from the group consisting of Sn, In, Ga, and Sb.

16. The light-emitting element according to claim 1,
wherein the first shell further contains at least one metal chalcogenide compound selected from the group consisting of SnS₂, SnSe₂, In₂Se₃, In₂Te₃, Ga₂Se₃, Sb₂Se₃, and Sb₂Te₃.

17. The light-emitting element according to claim 1,
wherein the first shell further contains at least one metal chalcogenide complex selected from the group consisting of Sn₂S₆⁴⁻, Sn₂Se₆⁴⁻, In₂Se₄²⁻, In₂Te₄²⁻, Ga₂Se₄²⁻, Sb₂Se₄²⁻, and Sb₂Te₄²⁻.

18. The light-emitting element according to claim 1,
wherein a volume ratio of a plurality of the spacer particles to the first light-emitting layer is 55% or more and 90% or less.

19. The light-emitting element according to claim 1, further comprising
a metal oxide semiconductor provided between the first light-emitting layer and either the first electrode or the second electrode,
wherein the first light-emitting layer and the metal oxide semiconductor are in contact with each other.

20. A display device, comprising
a plurality of light-emitting elements,
wherein each of the plurality of light-emitting elements includes:
a first electrode;
a second electrode disposed across from the first electrode; and
a first light-emitting layer disposed between the first electrode and the second electrode, and including a plurality of first quantum dots and a spacer particle, the plurality of first quantum dots each including a first core and a first shell coating the first core and having an outermost layer containing either a metal chalcogenide complex or a metal chalcogenide compound,
the plurality of light-emitting elements include a first light-emitting element and a second light-emitting element,
the first light-emitting element includes, in the first light-emitting layer, a long-wavelength light-emitting core as the first core and a first spacer particle as the spacer particle,
the second light-emitting element includes, in the first light-emitting layer, a short-wavelength light-emitting core as the first core and a second spacer particle as the spacer particle,
the long-wavelength light-emitting core has a peak emission wavelength longer than a peak emission wavelength of the short-wavelength light-emitting core, and
the first spacer particle is larger in particle size than the second spacer particle.

21. A display device, comprising:
a first light-emitting element and a second light-emitting element,
wherein the first light-emitting element includes:
a first electrode;
a second electrode disposed across from the first electrode; and
a first light-emitting layer disposed between the first electrode and the second electrode, and including a plurality of first quantum dots and a spacer particle, the plurality of first quantum dots each including a first core and a first shell coating the first core and having an outermost layer containing either a metal chalcogenide complex or a metal chalcogenide compound,
the first light-emitting element includes, in the first light-emitting layer, the first core and the spacer particle,
the second light-emitting element includes:
a third electrode;
a fourth electrode disposed across from the third electrode; and
a second light-emitting layer disposed between the third electrode and the fourth electrode, and including a plurality of second quantum dots each including a third core having a peak emission wavelength shorter than a peak emission wavelength of the first core, and
the second light-emitting layer contains a less amount of a plurality of the spacer particles than the first light-emitting layer does.

22. The display device according to claim 21,
wherein each of the plurality of second quantum dots includes a third shell coating at least a portion of the third core and having an outermost layer containing either a metal chalcogenide complex or a metal chalcogenide compound.

23-24. (canceled)
